(19) United States
(12) Patent Application Publication
(10) Pub. No.: US 2025/0374488 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/218,196

(22) Filed: May 23, 2025

(30) Foreign Application Priority Data
May 29, 2024 (JP) 2024-087291

(51) Int. Cl. H05K 7/20

(52) U.S. Cl. CPC H05K 7/2039

(57) ABSTRACT

An electrical connection unit includes a first circuit constitution body, a second circuit constitution body, and a heat dissipation portion. The first circuit constitution body includes a plurality of first electronic components and a first board on which the plurality of first electronic components are mounted. The second circuit constitution body includes a plurality of second electronic components and a second board on which the plurality of second electronic components are mounted. The heat dissipation portion is provided to overlap at least part of each of the first board and the second board, and is thermally connected to each of the first board and the second board. The electrical connection unit is switchable between a first state in which an amount of heat generation of the first circuit constitution body is greater than an amount of heat generation of the second circuit constitution body and a second state, different from the first state, in which the amount of heat generation of the second circuit constitution body is greater than the amount of heat generation of the first circuit constitution body.

### BACKGROUND OF THE INVENTION

### Field of the Invention

Embodiments of the present invention relate to an electrical connection unit. Priority is claimed on Japanese Patent Application No. 2024-087291 filed in Japan on May 29, 2024, the content of which is incorporated herein by reference.

### Description of the Related Art

There is an electrical connection unit including a plurality of electronic components.

### PRIOR ART DOCUMENT

### Patent Document

Patent Document 1: Japanese Unexamined Patent Application, First Publication No. 2024-037492

### SUMMARY OF THE INVENTION

Incidentally, it is expected to improve a heat dissipation property of an electrical connection unit.

An embodiment provides an electrical connection unit capable of improving a heat dissipation property.

An electrical connection unit according to an embodiment includes a first circuit constitution body, a second circuit constitution body, and a heat dissipation portion. The first circuit constitution body includes a plurality of first electronic components and a first board on which the plurality of first electronic components are mounted. The second circuit constitution body includes a plurality of second electronic components and a second board on which the plurality of second electronic components are mounted. The heat dissipation portion is provided to overlap at least part of each of the first board and the second board, and is thermally connected to each of the first board and the second board. The electrical connection unit is switchable between a first state in which an amount of heat generation of the first circuit constitution body is greater than an amount of heat generation of the second circuit constitution body and a second state, different from the first state, in which the amount of heat generation of the second circuit constitution body is greater than the amount of heat generation of the first circuit constitution body.

According to one embodiment, it is possible to provide an electrical connection unit capable of improving a heat dissipation property.

### BRIEF DESCRIPTION OF THE DRAWINGS

FIG. 1 is a cross-sectional view illustrating an electrical connection unit according to an embodiment;

FIG. 2 is a perspective view for describing a main body of the embodiment;

FIG. 3 is a perspective view for describing a subunit of the embodiment;

FIG. 4 is a partially exploded perspective view of the subunit of the embodiment;

FIG. 5 is a perspective view illustrating a routing board of the embodiment;

FIG. 6 is a partially exploded perspective view of the routing board according to the embodiment;

FIG. 7 is a cross-sectional view taken along line F7-F7 in FIG. 4;

FIG. 8 is a plan view illustrating the routing board of the embodiment;

FIG. 9 is a partially exploded perspective view of the electrical connection unit according to the embodiment;

FIG. 10 is a bottom view illustrating the routing board of the embodiment; and

FIG. 11 is a cross-sectional view taken along line F11-F11 of the structure illustrated in FIG. 8.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the specific constitution described below does not limit an applicable scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. “Accommodation” is not limited to a case where the entire component is accommodated, and may include a case where only part of the component is accommodated. The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

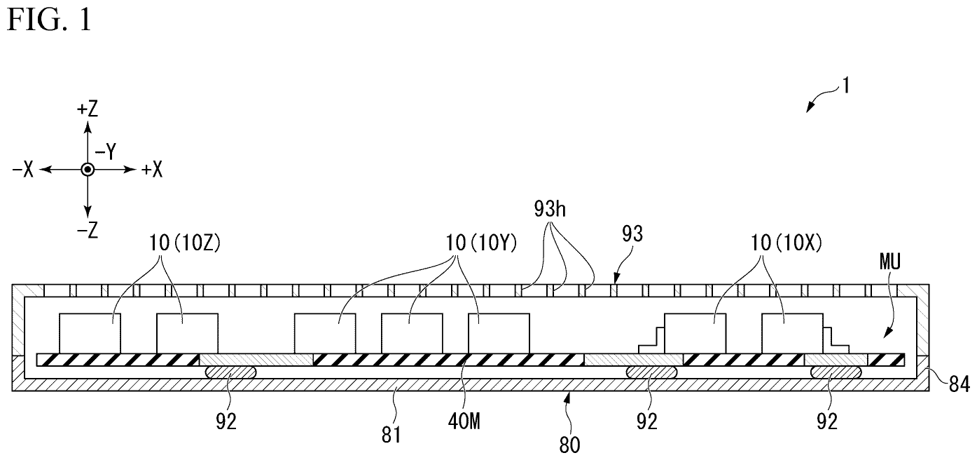

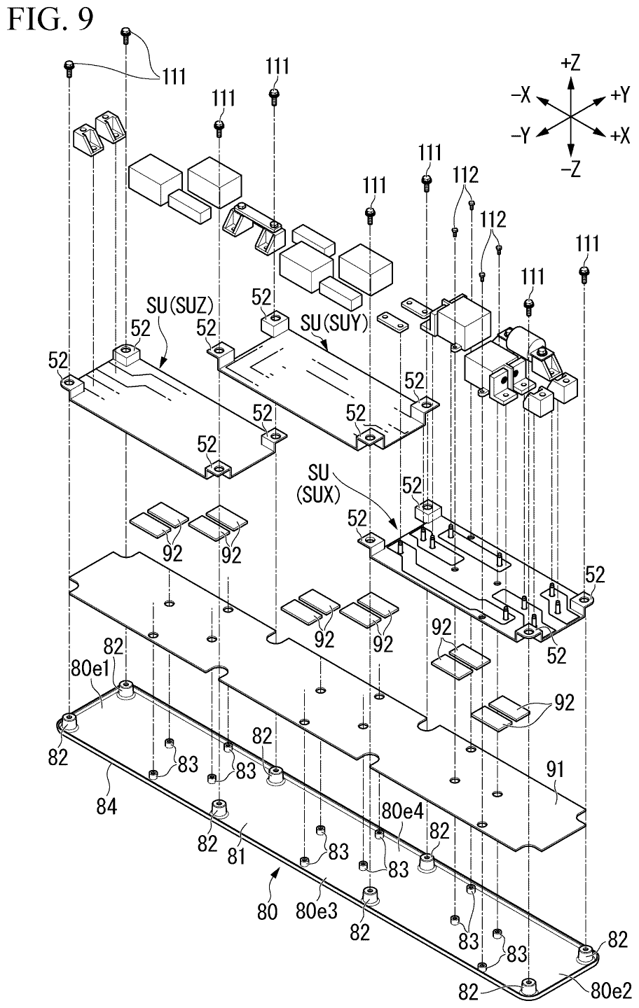

In the present disclosure, a +X direction, a −X direction, a +Y direction, a-Y direction, a +Z direction, and a −Z direction are defined as follows. The +X direction is a direction from a first end 80e1 to a second end 80e2 of a metal plate 80 that will be described later (see FIG. 9). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 9). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”. The X direction is an example of a “second direction”.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### <1. Constitution of Electrical Connection Unit 1>

FIG. 1 is a cross-sectional view illustrating an electrical connection unit 1 of an embodiment.

The electrical connection unit 1 illustrated in FIG. 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

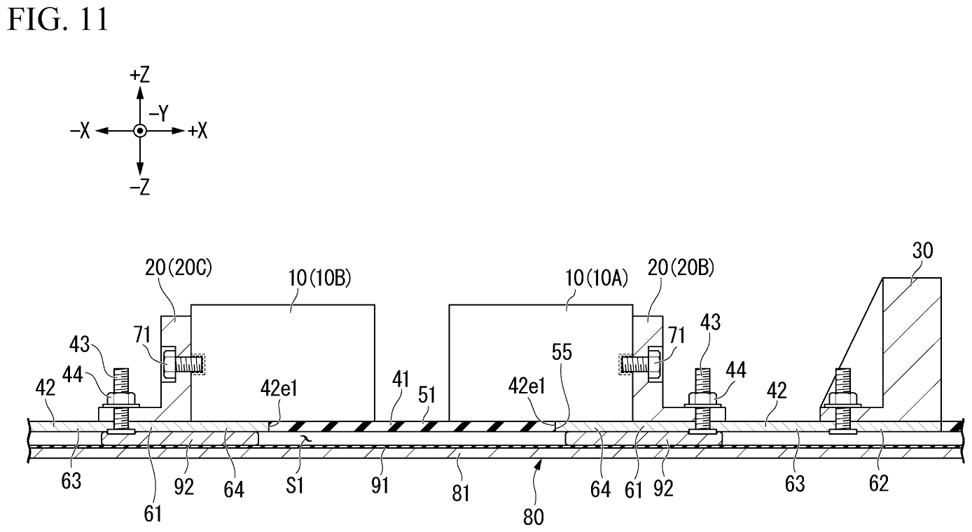

The electrical connection unit 1 includes, for example, a main body MU, a metal plate 80, an insulating sheet 91 (see FIG. 11), a plurality of heat transfer members 92, and an insulating cover 93.

### <2. Main Body MU>

First, the main body MU will be described.

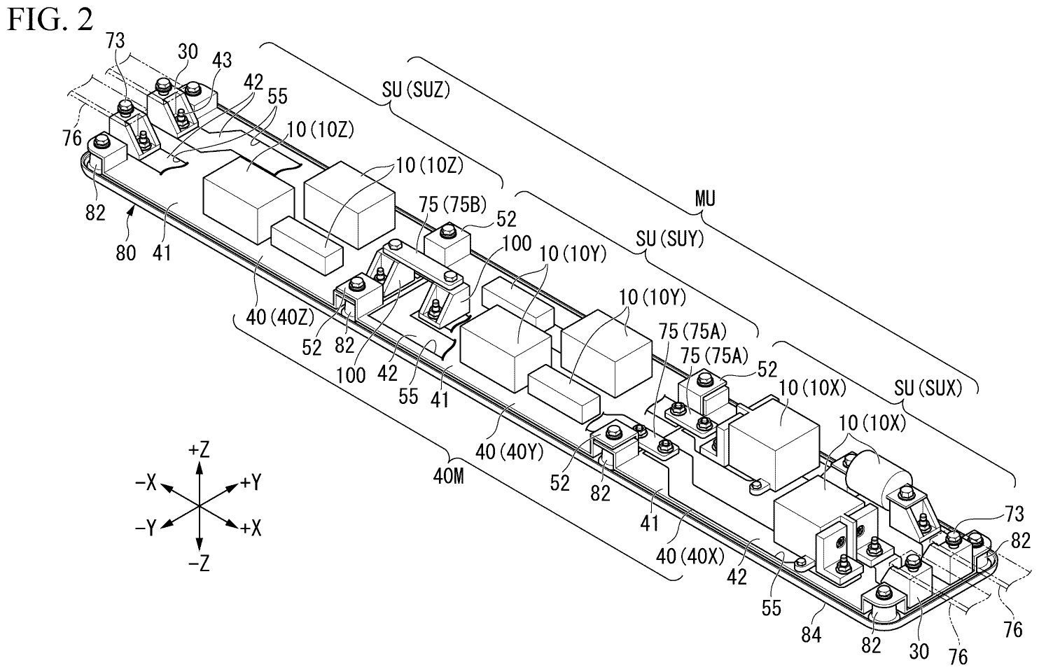

FIG. 2 is a perspective view for describing the main body MU.

The main body MU illustrated in FIG. 2 is a portion that performs a main function (for example, switching of electrical connection states or overcurrent protection) of the electrical connection unit 1. The main body MU is divided into, for example, a plurality of subunits SU. The main body MU is formed by, for example, connecting a plurality of subunits SU. In the present embodiment, the main body MU includes three subunits SU (first to third subunits SUX, SUY, and SUZ). Each subunit SU may be referred to as a “circuit constitution body”.

The first subunit SUX has a first electrical function. The first subunit SUX includes, for example, a plurality of electronic components 10X and a first routing board 40X. The plurality of electronic components 10X are electrically connected to the first routing board 40X. The electronic components 10X is an example of a “first electronic component”. The first subunit SUX is an example of a “first circuit constitution body”. The first routing board 40X is an example of a “first board”.

The second subunit SUY has a second electrical function. The second function is a function different from the first function. The second subunit SUY includes, for example, a plurality of electronic components 10Y and a second routing board 40Y. The plurality of electronic components 10Y are electrically connected to the second routing board 40Y. The electronic component 10Y is an example of a “first electronic component”. The second subunit SUY is an example of a “first circuit constitution body”. The second routing board 40Y is an example of a “first board”.

The third subunit SUZ has a third electrical function. The third function is a function different from the first function and the second function. The third subunit SUZ includes, for example, a plurality of electronic components 10Z and a third routing board 40Z. The plurality of electronic components 10Z are electrically connected to the third routing board 40Z. The electronic component 10Z is an example of a “second electronic component”. The third subunit SUZ is an example of a “second circuit constitution body”. The third routing board 40Z is an example of a “second board”.

In the present embodiment, the three subunits SUX, SUY, and SUZ are disposed to be arranged in the X direction. For example, the first subunit SUX is disposed on the +X direction side with respect to the second subunit SUY. The first subunit SUX and the second subunit SUY are electrically connected via a coupling bus bar 75 extending between the first routing board 40X and the second routing board 40Y. On the other hand, the third subunit SUZ is disposed on the −X direction side with respect to the second subunit SUY. The third subunit SUZ and the second subunit SUY are electrically connected via the coupling bus bar 75 extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. One large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the first subunit SUX, the second subunit SUY, and the third subunit SUZ are not distinguished, the subunits will be simply referred to as “subunit SU”. In a case where the electronic component 10X, the electronic component 10Y, and the electronic component 10Z are not distinguished, the electronic components will be simply referred to as “electronic component 10”. When the first routing board 40X, the second routing board 40Y, and the third routing board 40Z are not distinguished, the routing boards will be simply referred to as “routing board 40”.

### <3. Constitution of Subunit SU>

Next, a constitution of the subunit SU will be described.

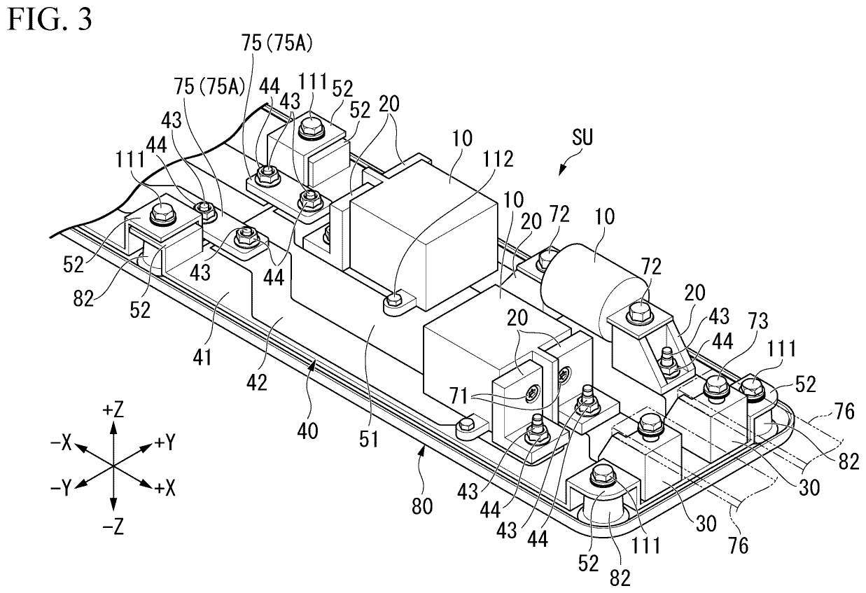

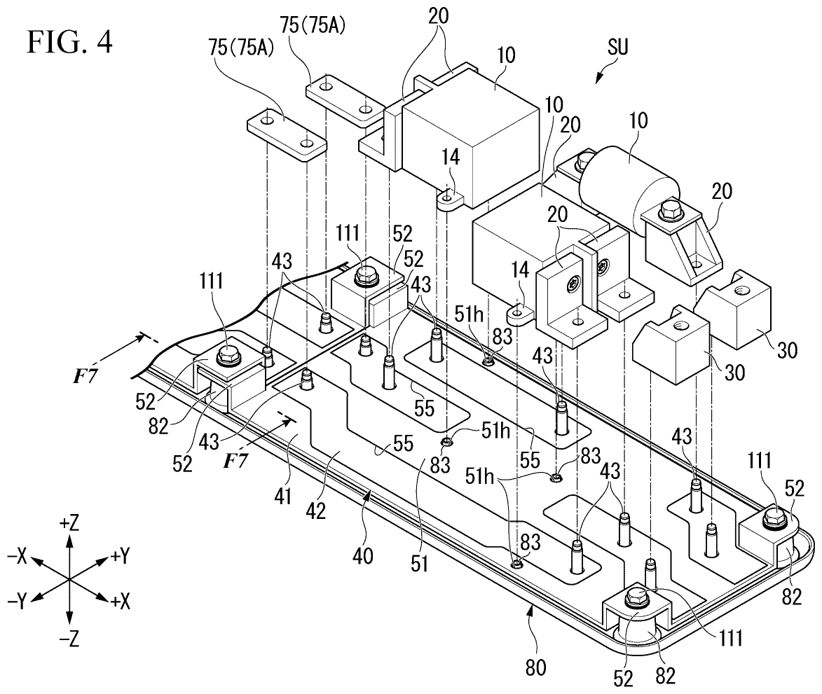

FIG. 3 is a perspective view for describing the subunit SU. FIG. 4 is a partially exploded perspective view of the subunit SU.

As illustrated in FIGS. 3 and 4, the subunit SU includes, for example, a plurality of electronic components 10, a plurality of connection components 20 for component connection, a plurality of connection components 30 for external connection, a routing board 40, a plurality of fastening members 71, 72, and 73, and a connection component 100 for unit connection (see FIG. 2).

### <3.1 Electronic Component 10 and Connection Component 20 for Component Connection>

First, the electronic component 10 and the connection component 20 will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization.

The connection component 20 is a component that electrically connects the electronic component 10 to the routing board 40. The connection component 20 forms part of an energization path in the subunit SU. The connection component 20 is made of a metal (for example, copper or a copper alloy). The connection component 20 is provided in a state of standing on the +Z direction side from the routing board 40. A first end (end on the −Z direction side) of the connection component 20 is connected to the bus bar 42 via a fastening member 43 (for example, a bolt). A second end (end on the +Z direction side) of the connection component 20 is connected to the electronic component 10 via a fastening member 71 (for example, a screw or a bolt).

### <3.2 Connection Component 30 for External Connection>

Next, the connection component 30 for external connection will be described.

The connection component 30 is a component that electrically connects the external connection bus bar 76 to the routing board 40. In the present embodiment, the connection component 30 electrically connects the external connection bus bar 76 to the bus bar 42 included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of a vehicle. However, the external device is not limited to a battery unit or an inverter.

Similarly to the connection component 20, the connection component 30 is made of a metal (for example, copper or a copper alloy). As illustrated in FIG. 2, the connection component 30 is provided in a state of standing on the +Z direction side at the outer peripheral portion (the end on the X direction side) of the routing board 40M. A first end (an end on the −Z direction side) of the connection component 30 is connected to the bus bar 42 via a fastening member 43 (for example, a bolt). A second end (an end on the +Z direction side) of the connection component 20 is connected to the external connection bus bar 76 via a fastening member 73 (for example, a screw or a bolt).

### <3.3 Connection Component 100 for Unit Connection>

Next, the connection component 100 for unit connection will be described.

The connection component 100 electrically connects the adjacent subunits SU. In the present embodiment, the connection component 100 connects the bus bar 42 included in one subunit SU (for example, the second subunit SUY) to the bus bar 42 included in the other subunit SU (for example, the third subunit SUZ) among the adjacent subunits SU.

### <3.4 Routing Board 40>

First, the routing board 40 will be described.

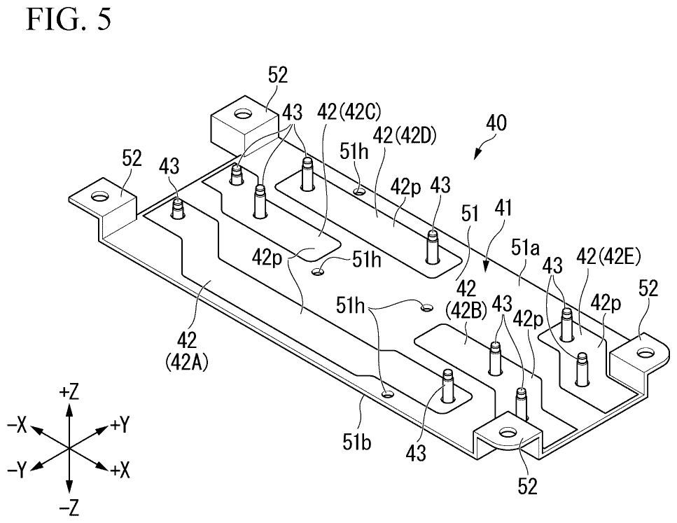

FIG. 5 is a perspective view illustrating the routing board 40.

As illustrated in FIG. 5, the routing board 40 is a member that forms at least part of an energization path between the plurality of electronic components 10 and/or at least part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding. Among the bus bars 42, the bus bars 42 provided in the first subunit SUX and the second subunit SUY are an example of a “first bus bar”. Among the bus bars 42, the bus bar 42 provided in the third subunit SUZ is an example of a “second bus bar”.

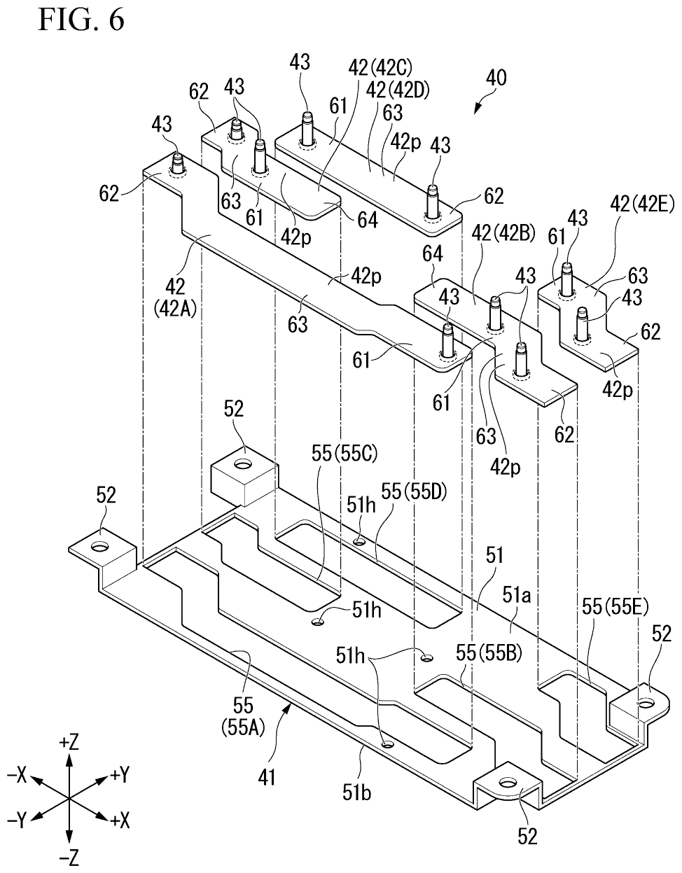

FIG. 6 is a partially exploded perspective view of the routing board 40. Hereinafter, for convenience of description, the base plate 41, the bus bars 42, and the fastening members 43 will be described with reference to the drawings in which the routing board 40 is partially exploded.

### (Base Plate 41)

As illustrated in FIG. 6, the base plate 41 is a holding member that integrally holds the plurality of bus bars 42 arranged in the horizontal direction at intervals. The base plate 41 is made of, for example, synthetic resin and has an insulating property. The base plate 41 is formed in, for example, a rectangular shape in which the X direction is a longitudinal direction and the Y direction is a lateral direction. The base plate 41 electrically insulates the plurality of bus bars 42 from each other. The base plate 41 includes, for example, a flat surface portion 51 and a plurality of fixing portions 52.

The flat surface portion 51 is a portion formed in a plate shape in the base plate 41. The flat surface portion 51 forms a main portion of the base plate 41. The flat surface portion 51 spreads in the horizontal direction. In the present embodiment, the flat surface portion 51 extends over the entire width in the X direction of the base plate 41 and over the entire width in the Y direction of the base plate 41 except for the four corner portions of the base plate 41.

The flat surface portion 51 has a first surface 51a and a second surface 51b. The first surface 51a is a surface directed toward the +Z direction side. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed toward the −Z direction side. The second surface 51b is a flat surface provided in the horizontal direction. The second surface 51b faces the metal plate 80 (see FIG. 1). A thickness direction (plate thickness direction) of the flat surface portion 51 is the Z direction.

In the flat surface portion 51, for example, one or more (for example, a plurality of) accommodation portions 55 in which the bus bars 42 are accommodated are formed. The plurality of accommodation portions 55 are formed apart from each other in the X direction or the Y direction. Each of the accommodation portions 55 is, for example, a through-hole penetrating the flat surface portion 51 in the Z direction. That is, each accommodation portion 55 is open in the Z direction on both the first surface 51a and the second surface 51b. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41). As illustrated in FIG. 2, among the accommodation portions 55, the accommodation portions 55 provided in the first subunit SUX and the second subunit SUY are an example of a “first accommodation portion”. Among the accommodation portions 55, the accommodation portion 55 provided in the third subunit SUZ is an example of a “second accommodation portion”.

As illustrated in FIG. 6, each accommodation portion 55 is formed in an outer shape corresponding to the shape of the accommodated bus bar 42 when viewed from the Z direction. In the present embodiment, the flat surface portion 51 includes, for example, five accommodation portions 55A, 55B, 55C, 55D, and 55E as the plurality of accommodation portions 55.

In the flat surface portion 51, a through-hole 51h is formed at a position shifted in the X direction or the Y direction with respect to the accommodation portion 55. As illustrated in FIG. 4, the through-hole 51h is formed, for example, at a position overlapping the attachment portion 14 of the electronic component 10 when viewed from the Z direction. The attachment portion 14 is a portion for attaching the electronic component 10 to the metal plate 80. The attachment portion 14 protrudes in the X direction or the Y direction from a −Z direction-side end of the case of the electronic component 10.

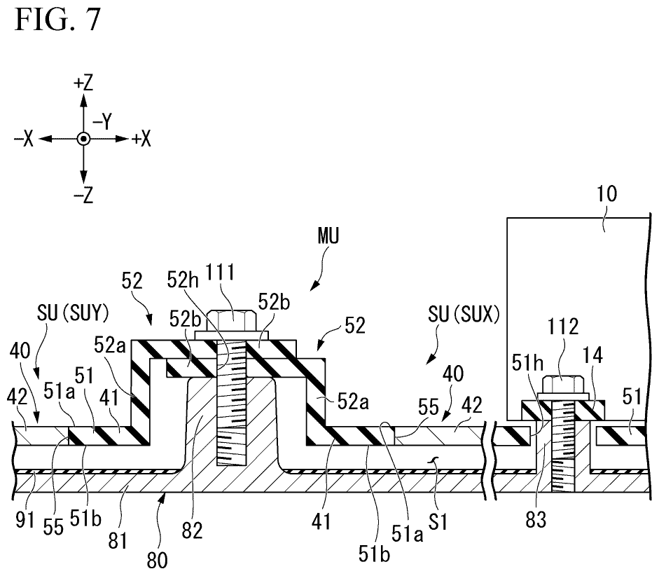

FIG. 7 is a cross-sectional view taken along line F7-F7 in FIG. 4.

As illustrated in FIGS. 4 and 7, the fixing portion 52 is a portion used for fixing the metal plate 80 and the base plate 41. The fixing portion 52 is provided at a corner portion of the base plate 41. The fixing portion 52 includes, for example, a standing plate portion 52a and a horizontal plate portion 52b.

The standing plate portion 52a stands on the +Z direction side from the end of the flat surface portion 51 of the base plate 41. The standing plate portion 52a is formed in, for example, an L shape when viewed from the Z direction. That is, the standing plate portion 52a extends in the Z direction in a state in which a part thereof in the horizontal direction is open.

The horizontal plate portion 52b extends in the horizontal direction from the end of the standing plate portion 52a on the +Z direction side. The horizontal plate portion 52b is a plate portion provided in the horizontal direction. The horizontal plate portion 52b extends in an eaves shape to cover a portion surrounded by the standing plate portion 52a from the +Z direction side.

### (Bus bar 42)

As illustrated in FIGS. 5 and 6, the bus bar 42 is a routing member (electrical connection member) included in the routing board 40. The bus bar 42 is, for example, a routing member for electrically connecting the plurality of electronic components 10 to each other. The bus bar 42 may be a routing member for connecting one electronic component 10 to an external device. The bus bar 42 is made of a metal (for example, copper or a copper alloy) and has conductivity. In the present embodiment, the routing board 40 includes, for example, five bus bars 42A, 42B, 42C, 42D, 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E are held by the flat surface portion 51 of the base plate 41.

At least part of each bus bar 42 has a plate shape formed in the horizontal direction. At least part of each bus bar 42 extends along the flat surface portion 51 in a state of being accommodated in the accommodation portion 55. At least part of each bus bar 42 extends along the first surface 51a of the flat surface portion 51. At least part of each bus bar 42 extends in the horizontal direction in the accommodation portion 55. In the present embodiment, each bus bar 42 has a plate shape formed in the horizontal direction over the entire bus bar 42. Each of the bus bars 42 extends along the flat surface portion 51 in a state of being accommodated in the accommodation portion 55 over the entire length of the bus bar 42. Hereinafter, in each bus bar 42, a portion accommodated in the accommodation portion 55 (a portion extending along the flat surface portion 51) may be referred to as a “plate portion 42p”.

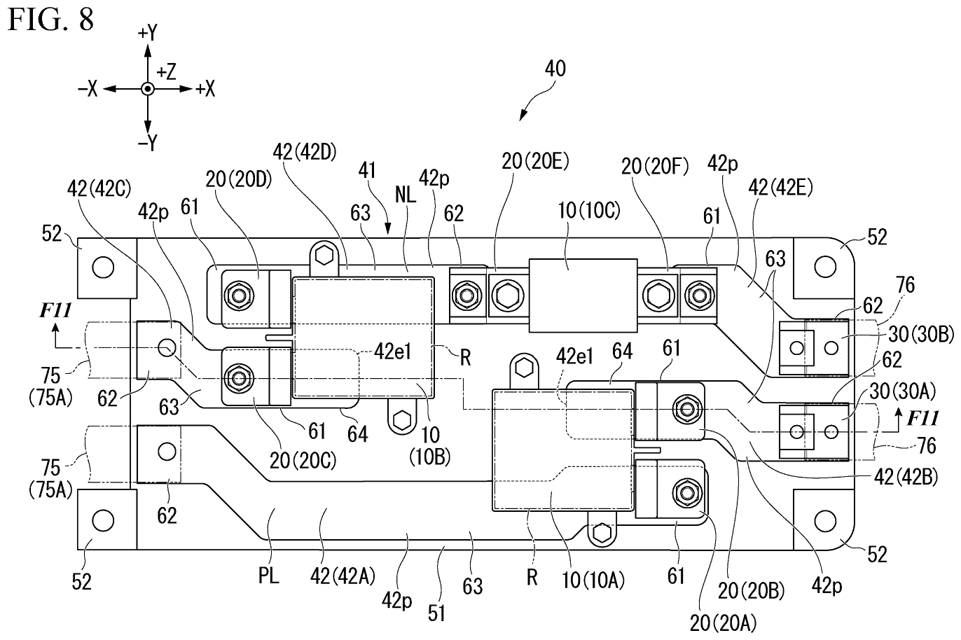

FIG. 8 is a plan view illustrating the routing board 40.

As illustrated in FIG. 8, the plate portion 42p of each bus bar 42 includes, for example, a first connection portion 61, a second connection portion 62, and an extending portion 63.

The first connection portion 61 is a portion in contact with one connection component 20 (hereinafter referred to as a “first connection component 20”) among the plurality of connection components 20. The first connection component 20 is a connection component that connects one electronic component 10 (hereinafter referred to as a “first electronic component 10”) among the plurality of electronic components 10 to the bus bar 42. The first connection portion 61 is a portion of the bus bar 42 overlapping the first connection component 20 when viewed from the Z direction. The first connection portion 61 is adjacent to the first connection component 20 in the Z direction. The first connection portion 61 is connected to the first connection component 20 from the Z direction.

The second connection portion 62 is a portion in contact with the connection component 20 (hereinafter referred to as a “second connection component 20”) different from the first connection component 20 among the plurality of connection components 20. The second connection component 20 is a connection component that connects the electronic component 10 (hereinafter referred to as a “second electronic component 10”) different from the first electronic component 10 among the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction. The second connection portion 62 is connected to the second connection component 20 from the Z direction.

The second connection portion 62 may be a portion in contact with the connection component 30. The connection component 30 is a connection component for connecting an external device to the bus bar 42. In this case, the second connection portion 62 is a portion of the bus bar 42 overlapping the connection component 30 when viewed from the Z direction. The second connection portion 62 is adjacent to the connection component 30 in the Z direction. The second connection portion 62 is connected to the connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction. The second connection portion 62 is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 extends along the flat surface portion 51 in a state of being accommodated in the accommodation portion 55 at least over the first connection portion 61 and the second connection portion 62. For example, the first connection portion 61, the second connection portion 62, and the extending portion 63 extend along the flat surface portion 51 in a state of being accommodated in the accommodation portion 55. A portion of each bus bar 42 accommodated in the accommodation portion 55 is exposed on the first surface 51a and the second surface 51b of the flat surface portion 51. That is, the surface of each bus bar 42 directed in the Z direction is exposed to the outside of the base plate 41 (for example, in the +Z direction and the −Z direction) through the opening of the accommodation portion 55. However, part of the bus bar 42 may be buried in the base plate 41.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends linearly in the X direction. The extending portion 63 extends over a region R overlapping the electronic component 10 when viewed from the Z direction, over the +X direction side and the −X direction side of the region R.

The one or more bus bars 42 may have an extension 64 in addition to the first connection portion 61, the second connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 extends along the flat surface portion 51 in a state of being accommodated in the accommodation portion 55. The extension 64 is accommodated in the accommodation portion 55 to extend to the region R overlapping the electronic component 10 when viewed from the Z direction. The extension 64 has an end 42el of the bus bar 42 at a position overlapping the region R when viewed from the Z direction.

Some routing examples of the bus bar 42 will be described below. The plurality of electronic components 10 include three electronic components 10A, 10B, and 10C. The plurality of connection components 20 include six connection components 20A, 20B, 20C, 20D, 20E, and 20F. The plurality of connection components 30 include two connection components 30A and 30B.

### (First Routing Example)

First, a routing example related to the bus bar 42A will be described.

The bus bar 42A includes a first connection portion 61, a second connection portion 62, and an extending portion 63. The first connection portion 61 is located on the +X direction side with respect to the electronic component 10A when viewed from the Z direction. The first connection portion 61 is electrically connected to, for example, a positive electrode terminal of the electronic component 10A via the connection component 20A. The second connection portion 62 is located on the −X direction side with respect to the electronic component 10A when viewed from the Z direction. The second connection portion 62 is electrically connected to another subunit SU via the coupling bus bar 75.

The extending portion 63 is accommodated in the accommodation portion 55 to extend over both sides of the region R through the region R overlapping the electronic component 10A when viewed from the Z direction. For example, the extending portion 63 extends linearly in the X direction. The extending portion 63 extends over the region R overlapping the electronic component 10A when viewed from the Z direction, over the +X direction side and the −X direction side of the region R. The bus bar 42A is, for example, a bus bar included in the positive electrode line PL included in the electrical connection unit 1.

### (Second Routing Example)

Next, a routing example related to the bus bar 42B will be described.

The bus bar 42B has a first connection portion 61, a second connection portion 62, an extending portion 63, and an extension 64. The first connection portion 61 is electrically connected to, for example, a negative electrode terminal of the electronic component 10A via the connection component 20B different from the first connection component 20. The second connection portion 62 is electrically connected to the external connection bus bar 76 via the connection component 30A. The extension 64 extends to the region R overlapping the electronic component 10A when viewed from the Z direction. The extension 64 has an end 42el of the bus bar 42 at a position overlapping the region R when viewed from the Z direction. Note that the extending portion 63 of the bus bar 42B may extend over both sides of the region R through the region R overlapping the electronic component 10 when viewed from the Z direction, similarly to the extending portion 63 of the bus bar 42A. The bus bar 42B is, for example, a bus bar included in the positive electrode line PL included in the electrical connection unit 1.

### (Third Routing Example)

Next, a routing example related to the bus bar 42C will be described.

The bus bar 42C includes a first connection portion 61, a second connection portion 62, an extending portion 63, and an extension 64. The first connection portion 61 is electrically connected to, for example, a negative electrode terminal of the electronic component 10B via the connection component 20C. The second connection portion 62 is electrically connected to another subunit SU via the coupling bus bar 75. The extension 64 extends to a region R overlapping the electronic component 10B when viewed from the Z direction. In the extension 64, the bus bar 42C having the end 42el of the bus bar 42 at a position overlapping the region R when viewed from the Z direction is, for example, a bus bar included in a negative electrode line NL of the electrical connection unit 1.

### (Fourth Routing Example)

Next, a routing example related to the bus bar 42D will be described.

The bus bar 42D has a first connection portion 61, a second connection portion 62, and an extending portion 63. The first connection portion 61 is electrically connected to, for example, a positive electrode terminal of the electronic component 10B via the connection component 20D. The second connection portion 62 is electrically connected to, for example, a negative electrode terminal of the electronic component 10C via the connection component 20E. The bus bar 42D is, for example, a bus bar included in the negative electrode line NL included in the electrical connection unit 1.

### (Fifth Routing Example)

Next, a routing example related to the bus bar 42E will be described.

The bus bar 42E includes a first connection portion 61, a second connection portion 62, and an extending portion 63. The first connection portion 61 is electrically connected to, for example, a negative electrode terminal of the electronic component 10C via the connection component 20F. The second connection portion 62 is electrically connected to the external connection bus bar 76 via the connection component 30B. The bus bar 42E is, for example, a bus bar included in the negative electrode line NL included in the electrical connection unit 1.

### (Fastening Member 43)

Next, referring to FIG. 6 again, the fastening member 43 will be described.

The fastening member 43 is a component for fixing the bus bar 42 and a connection target component (the connection component 20, the connection component 30, or the coupling bus bar 75) of the bus bar 42. The fastening member 43 is, for example, a caulking bolt fixed to the bus bar 42. The fastening member 43 penetrates the bus bar 42 in the Z direction. The fastening member 43 is electrically and physically connected to the bus bar 42 in a state of protruding toward the +Z direction side from the bus bar 42. Note that the fastening member 43 is not limited to caulking fixation and may be fixed to the bus bar 42 through welding or other methods.

The connection component 20 is fixed to the fastening member 43 while being previously fixed to the electronic component 10 via the fastening member 71 or the fastening member 72. For example, the fastening member 43 penetrates the first end of the connection component 20. As illustrated in FIG. 3, an engagement member 44 (for example, a nut) is attached to a portion of the fastening member 43 protruding toward the +Z direction side from the connection component 20. With this attachment, the connection component 20 is mounted on the routing board 40. In the present disclosure, the phrase “an electronic component is mounted on a board” is not limited to a case where the electronic component is directly connected to the board, and includes a case where the electronic component is connected to the board via another component (for example, the connection component 20). In the present disclosure, the phrase “an electronic component is mounted on a board” indicates that at least the electronic component is electrically connected to the board, and includes a case where the electronic component is fixed to a member (for example, the metal plate 80) different from the board instead of/in addition to the board.

### <4. Connection Structure>

Next, a connection structure of the subunit SU will be described.

As illustrated in FIG. 2, the first subunit SUX, the second subunit SUY, and the third subunit SUZ are arranged in this order from the +X direction side to the −X direction side. The first subunit SUX and the second subunit SUY are electrically connected via a coupling bus bar 75A. The second subunit SUY and the third subunit SUZ are electrically and physically connected via a coupling bus bar 75B.

The adjacent subunits SU are disposed in a state in which the ends facing each other in the X direction overlap each other in the Z direction. Specifically, the fixing portion 52 (horizontal plate portion 52b) located on the +X direction side in the second subunit SUY overlaps the fixing portion 52 (horizontal plate portion 52b) located on the −X direction side in the first subunit SUX from the +Z direction side. The fixing portion 52 (horizontal plate portion 52b) located on the −X direction side in the second subunit SUY overlaps the fixing portion 52 (horizontal plate portion 52b) located on the +X direction side in the third subunit SUX from the +Z direction side.

### <5. Metal Plate 80, Insulating Sheet 91, Heat Transfer Member 92, and Insulating Cover 93>

Next, the metal plate 80, the insulating sheet 91, the heat transfer member 92, and the insulating cover 93 will be described.

### <5.1 Metal Plate>

FIG. 9 is a partially exploded perspective view of the electrical connection unit 1. The metal plate 80 is a member for securing rigidity of the electrical connection unit 1 and enhancing a heat dissipation property of the electrical connection unit 1. The metal plate 80 is made of a metal (for example, aluminum or an aluminum alloy). The metal plate 80 is an example of a “heat dissipation portion”. The heat dissipation portion is not limited to a metal, and various materials can be applied as long as the heat dissipation portion is made of a material having excellent thermal conductivity compared with, for example, the base plate 41.

The metal plate 80 has a rectangular shape formed in the X direction when viewed from the Z direction. The metal plate 80 has a first end 80e1, a second end 80e2, a third end 80e3, and a fourth end 80e4. The first end 80el and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. In the present embodiment, the metal plate 80 has a size that covers the entire three subunits SU (main body MU) from below. Specifically, the length of the metal plate 80 in the X direction is larger than the length of the main body MU in the X direction. The length of the metal plate 80 in the Y direction is larger than the length of the main body MU in the Y direction. Therefore, when viewed from the Z direction, the area of the metal plate 80 is larger than the area of the main body MU.

The metal plate 80 includes, for example, a flat surface portion 81, a plurality of fixing portions 82, a plurality of fixing portions 83, and a peripheral wall portion 84.

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the entire three subunits SU (main body MU) from below. The flat surface portion 81 faces the routing boards 40 of the three subunits SU. In the present embodiment, the metal plate 80 faces the second surface 51b of each subunit SU with a gap S1 (see FIG. 7) between the metal plate 80 and the flat surface portion 51 (second surface 51b) of each subunit SU.

As illustrated in FIGS. 7 and 9, the fixing portion 82 is a portion for fixing the base plate 41 of each subunit SU to the metal plate 80. The fixing portion 82 is provided at a position corresponding to the fixing portion 52 of each subunit SU when viewed from the Z direction. The fixing portion 82 is a cylindrical or prismatic boss protruding in the +Z direction from the flat surface portion 81 of the metal plate 80.

The fixing portion 83 is a portion for directly fixing the electronic component 10 of each subunit SU to the metal plate 80 without using the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The amount of protrusion of the fixing portion 83 in the Z direction is smaller than the amount of protrusion of the fixing portion 82 in the Z direction.

As illustrated in FIG. 2, the peripheral wall portion 84 extends from the outer peripheral edge of the flat surface portion 81 toward the +Z direction side. The peripheral wall portion 84 extends over the entire periphery of the flat surface portion 81. The length of the peripheral wall portion 84 in the Z direction is shorter than the lengths of the fixing portions 82 and 83 in the Z direction.

### <5.2 Insulating Sheet 91>

The insulating sheet 91 is an insulating member for electrically insulating the metal plate 80 and the bus bars 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 is provided to cover the entire flat surface portion 81 of the metal plate 80 from the +Z direction side. Therefore, the main body MU faces the metal plate 80 with the insulating sheet 91 interposed therebetween. The insulating sheet 91 is an example of an “insulating member”.

The insulating sheet 91 is attached to the flat surface portion 81 of the metal plate 80. A notch or an opening for avoiding the fixing portion 82 and the fixing portion 83 of the metal plate 80 is formed in the insulating sheet 91. In the present embodiment, the thickness of the insulating sheet 91 in the Z direction is smaller than the thickness of the peripheral wall portion 84 in the Z direction. Therefore, the insulating sheet 91 is positioned in the horizontal direction with respect to the metal plate 80 by being surrounded by the peripheral wall portion 84.

### <5.3 Heat Transfer Member 92>

As illustrated in FIG. 9, the heat transfer member 92 is a member for transferring heat generated by the electronic component 10 at the time of energization and/or heat generated by the bus bar 42 itself at the time of energization to the metal plate 80. The heat transfer member 92 is, for example, a heat transfer sheet (for example, a thermally conductive silicone sheet) having elasticity. However, the heat transfer member 92 is not limited to the above example, and may be a heat transfer member made of a thermally conductive gel or another material.

The plurality of heat transfer members 92 include, for example, one or more (for example, a plurality of) heat transfer members 92 corresponding to the first subunit SUX, one or more (for example, a plurality of) heat transfer members 92 corresponding to the second subunit SUY, and one or more (for example, a plurality of) heat transfer members 92 corresponding to the third subunit SUZ. The heat transfer member 92 corresponding to the first subunit SUX is disposed at a position overlapping the first subunit SUX when viewed from the Z direction, and transfers heat generated by the first subunit SUX to the metal plate 80. The heat transfer member 92 corresponding to the second subunit SUY is disposed at a position overlapping the second subunit SUY when viewed from the Z direction, and transfers heat generated by the second subunit SUY to the metal plate 80. The heat transfer member 92 corresponding to the third subunit SUZ is disposed at a position overlapping the third subunit SUZ when viewed from the Z direction, and transfers heat generated by the third subunit SUZ to the metal plate 80.

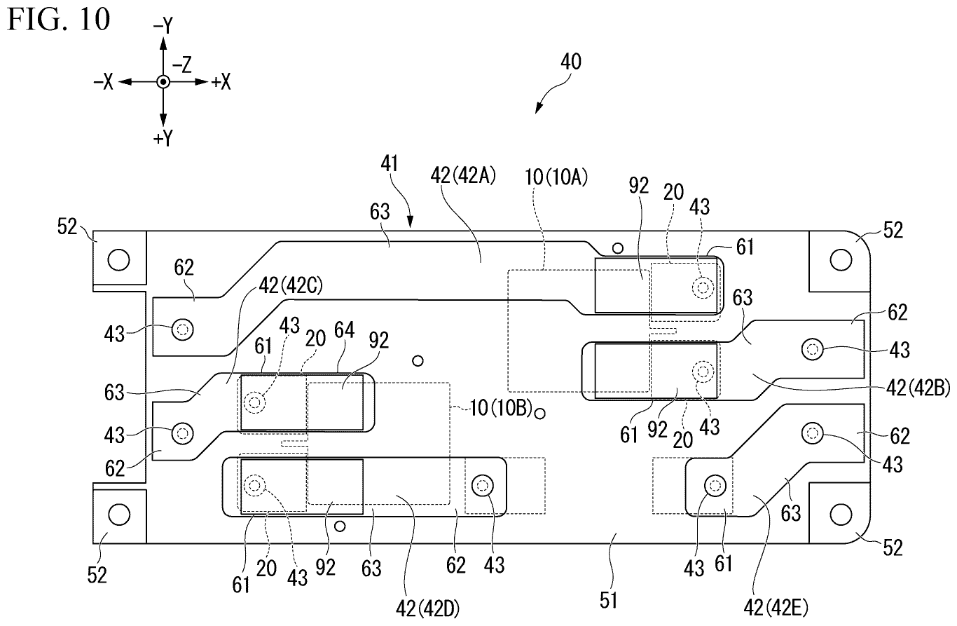

FIG. 10 is a bottom view illustrating the routing board 40.

As illustrated in FIG. 10, the heat transfer member 92 transfers heat transferred from the electronic component 10 to the bus bar 42 and/or heat generated by the bus bar 42 from the bus bar 42 to the metal plate 80. The plurality of heat transfer members 92 are partially provided in the routing board 40 in the horizontal direction. For example, the plurality of heat transfer members 92 are disposed at positions overlapping part of the bus bar 42 in the routing board 40 when viewed from the Z direction. The plurality of heat transfer members 92 are disposed at positions overlapping part of bus bar 42 in the vicinity of electronic components 10 (for example, the electronic components 10A and 10B) when viewed from the Z direction. In the present embodiment, the plurality of heat transfer members 92 are disposed at positions overlapping the connection component 20 (a connection portion between the bus bar 42 and the electronic component 10) when viewed from the Z direction.

FIG. 11 is a cross-sectional view taken along line F11-F11 of the structure illustrated in FIG. 8.

As illustrated in FIG. 11, the heat transfer member 92 is provided in a crushed state between the main body MU and the insulating sheet 91 in the Z direction. A portion of the heat transfer member 92 located on the −Z direction side is in contact with the metal plate 80 via the insulating sheet 91. The heat transfer member 92 may be provided between the insulating sheet 91 and the metal plate 80.

A portion of the heat transfer member 92 located on the +Z direction side is in contact with the bus bar 42. In the present embodiment, the heat transfer member 92 is in contact with the bus bar 42 at a position overlapping the connection component 20 when viewed from the Z direction. In this case, the heat transfer member 92 easily transfers the heat transferred from the electronic component 10 to the connection component 20 from the connection component 20 to the metal plate 80 via the bus bar 42. Part of the heat transfer member 92 is disposed at a position overlapping the fastening member 43 when viewed from the Z direction, and is in contact with the fastening member 43. In this case, the heat transfer member 92 easily transfers the heat transferred from the electronic component 10 to the connection component 20 from the fastening member 43 to the metal plate 80.

In the present embodiment, part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 11, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64.

### <5.4 Insulating Cover 93>

Referring to FIG. 1 again, the insulating cover 93 will be described. The insulating cover 93 is a member for securing safety of the main body MU with respect to the energization path. The insulating cover 93 is made of, for example, a synthetic resin and has an insulating property. The insulating cover 93 has, for example, a box shape that is open on the −Z direction side. The insulating cover 93 is attached to the metal plate 80 to cover the main body MU from the +Z direction side. In the present embodiment, a plurality of vent holes 93h are formed in the top wall of the insulating cover 93. Note that the insulating cover 93 is not limited to a box-shaped member, and may be a sheet-shaped member that covers the energization path of the main body MU.

### <6. Fixing Structure>

Next, a fixing structure of the subunit SU will be described.

As illustrated in FIG. 7, the main body MU is stacked on the metal plate 80 in the Z direction in a state in which the fixing portions 52 of the adjacent subunits SU overlap the fixing portion 82 of the metal plate 80. The fixing portions 52 and 82 overlapping each other in the Z direction are fixed to each other via the fastening member 111 (for example, a screw or a bolt). The fastening member 111 penetrates the fixing portion 52 of the subunit SU and is then fastened to the fixing portion 82 of the metal plate 80. Among the plurality of fixing portions 82, the fixing portion 82 fixed to the subunits SUX and SUY is an example of a “first support portion”. Among the plurality of fixing portions 82, the fixing portion 82 fixed to the subunit SUZ is an example of a “second support portion”.

In a state in which the main body MU and the metal plate 80 are stacked, the fixing portion 83 of the metal plate 80 penetrates the through-hole 51h of the subunit SU. The attachment portion 14 of the electronic component 10 overlaps the fixing portion 83 in the Z direction. The attachment portion 14 and the fixing portion 83 overlapping each other in the Z direction are fixed to each other via a fastening member 112 (for example, a screw or a bolt). The fastening member 112 penetrates the attachment portion 14 and is then fastened to the fixing portion 83 of the metal plate 80. A gap through which air can pass is provided between the inner circumferential surface of the through-hole 51h and the fixing portion 83.

Here, in the main body MU illustrated in FIG. 2, a heat generation timing of the third subunit SUZ among the three subunits SUX, SUY, and SUZ is set to be different from a heat generation timing of the remaining subunits SUX and SUY. In the present embodiment, the difference in the heat generation timing is not limited to a case where the third subunit SUZ and one subunit SU of the remaining subunits SUX and SUY generate heat when an amount of heat generation of the other subunit SU is zero. For example, in a case where all the subunits SU generate heat, an amount of heat generation of the third subunit SUZ in the same time period may be different from an amount of heat generation of the remaining subunits SUX and SUY. That is, the electrical connection unit 1 is switchable between a first state in which the amount of heat generation of the remaining subunits SUX and SUY is greater than the amount of heat generation of the third subunit SUZ, and a second state in which the amount of heat generation of the third subunit SUZ is smaller than the amount of heat generation of the remaining subunits SUX and SUY (alternatively, the amount of heat generation of at least one of the subunits SUX and SUY). In this case, the electrical connection unit 1 includes a case where the relatively high temperature subunit SU and the relatively low temperature subunit SU are switched even when not a little heat is generated in all the subunits SU.

For example, in a case where the remaining subunits SUX and SUY are used during traveling and the third subunit SUZ is used during charging in a state in which the electrical connection unit 1 is mounted on a vehicle, it can be said that heat generation timings of the third subunit SUZ and the remaining subunits SUX and SUY are different from each other. That is, traveling of the vehicle is an example of a “first state”. During traveling of the vehicle, for example, the amount of energization to the remaining subunits SUX and SUY becomes larger than the amount of energization to the third subunit SUZ, and the amount of heat generation of the remaining subunits SUX and SUY becomes larger than the amount of heat generation of the third subunit SUZ. On the other hand, charging of the vehicle is an example of a “second state”. During charging the vehicle, for example, the amount of energization to the third subunit SUZ becomes larger than the amount of energization to the remaining subunits SUX and SUY, and the amount of heat generation of the third subunit SUZ becomes greater than the amount of heat generation of the remaining subunits SUX and SUY. These heat generation timings are switched in response to a command from a control device mounted on the vehicle, for example. For example, the switching of the heat generation timings is performed by switching states of a relay included in the plurality of electronic components 10 of the electrical connection unit 1 in response to the command.

### <7. Heat Transfer>

As illustrated in FIG. 11, in the subunit SU, for example, heat is generated when the electronic component 10 is energized or when the bus bar 42 is energized. Part of the heat of the base plate 41 out of the heat generated in the subunit SU is transferred to the metal plate 80 (flat surface portion 81) via the heat transfer member 92 and the insulating sheet 91. Part of the heat of the base plate 41 is transferred to the fixing portion 82 of the metal plate 80 via the fixing portion 52. Further, part of the heat of the electronic component 10 is transmitted to the fixing portion 83 of the metal plate 80 via the attachment portion 14. As described above, the heat generated in the subunit SU is transferred to the metal plate 80 and then released from the metal plate 80 to the outside.

The electrical connection unit 1 of the present embodiment includes the subunits SUX and SUY having a plurality of electronic components 10X and 10Y and routing boards 40X and 40Y on which the plurality of electronic components 10X and 10Y are mounted, the subunit SUZ having a plurality of electronic components 10Z and the routing board 40Z on which the plurality of electronic components 10Z are mounted, and the metal plate 80 provided to overlap at least part of each of the routing boards 40X and 40Y and the routing board 40Z and thermally connected to each of the routing boards 40X and 40Y and the routing board 40Z. The electrical connection unit 1 is switchable between a first state in which the amount of heat generation in the subunits SUX and SUY is greater than the amount of heat generation in the subunit SUZ and a second state, different from the first state, in which the amount of heat generation in the subunit SUZ is greater than the amount of heat generation in the subunits SUX and SUY.

According to this constitution, the metal plate 80 is provided across the plurality of subunits SU. Then, the subunit SU thermally connected to the metal plate 80 switches between the first state and the second state in which the relative heating values are different. Therefore, in the first state, in addition to the portion of the metal plate 80 overlapping the subunits SUX and SUY, the portion overlapping the subunit SUZ can also be subjected to the release of the heat generated in the subunits SUX and SUY. On the other hand, in the second state, in addition to the portion of the metal plate 80 overlapping the subunit SUZ, the portion overlapping the subunits SUX and SUY can also be subjected to the release of the heat generated in the subunit SUZ. With this constitution, for example, compared with a case where the metal plate 80 is provided independently for each subunit SU, it is easy to secure a large volume of the metal plate 80 thermally connected to the subunit SU that is a heat generation target while reducing a dimension of the metal plate 80 in the Z direction. That is, since it is easy to secure the heat capacity of the metal plate 80 while reducing the dimension of the metal plate 80 in the Z direction, it is possible to provide the electrical connection unit 1 having an excellent heat dissipation property.

In the electrical connection unit 1 of the present embodiment, the subunits SUX, SUY, and SUZ are disposed to be arranged in the X direction.

According to this constitution, it is possible to reduce the thickness of the electrical connection unit 1 in the Z direction.

In the electrical connection unit 1 of the present embodiment, the area of the metal plate 80 as viewed from the Z direction is larger than the total area of the subunits SUX, SUY, and SUZ as viewed from the Z direction, and the metal plate 80 overlaps the entire subunits SUX, SUY, and SUZ when viewed from the Z direction.

According to this constitution, it is easy to uniformly transfer heat from the subunits SUX, SUY, and SUZ while securing the heat capacity of the metal plate 80. Through this transfer, a heat dissipation property can be further improved.

In the electrical connection unit 1 of the present embodiment, the insulating sheet 91 is provided between the metal plate 80 and the subunit SU.

According to this constitution, since the insulating sheet 91 is provided between the metal plate 80 and the subunit SU, insulation between the heat dissipation portion and the subunit SU can be secured. This insulation can improve the degree of freedom in selecting a material to be used for the heat dissipation portion.

In the electrical connection unit 1 of the present embodiment, the subunit SU includes the bus bar 42 that connects the plurality of electronic components 10 to each other, and the heat transfer member 92 having elasticity is provided between the metal plate 80 and each subunit SU. The heat transfer member 92 is disposed at a position overlapping a connection portion between the bus bar 42 and the electronic component 10 when viewed from the Z direction.

According to this constitution, in the subunit SU, the connection portion between the bus bar 42, which is one of heat generating portions, and the electronic component 10 is thermally connected to the metal plate 80 via the heat transfer member 92. With this connection, a heat dissipation property can be further improved.

In the electrical connection unit 1 of the present embodiment, the routing board 40 is provided with the accommodation portion 55 that is recessed in the Z direction or open in the Z direction and accommodates the bus bar 42.

According to this constitution, since the bus bar 42 is exposed to the outside of the routing board 40, heat generated in the bus bar 42 can be quickly released, and accumulation of heat in the routing board 40 can be curbed.

In the electrical connection unit 1 of the present embodiment, the metal plate 80 includes the flat surface portion 81 and the fixing portion 82 that protrudes from the flat surface portion 81 in the Z direction and supports the routing board 40.

According to this constitution, the heat of the routing board 40 is easily transferred to the metal plate 80 via the fixing portion 82. Through this transfer, a heat dissipation property can be further improved.

In the electrical connection unit 1 of the present embodiment, the subunits SU are electrically connected.

According to this constitution, by connecting the subunits SU in a state of being preassembled for each subunit SU, it is possible to improve assemblability and manufacturing efficiency. In addition, in the electrical connection unit 1 of the present embodiment, since the metal plate 80 is provided to straddle between the subunits SU, the rigidity at the connection portion between the subunits SU is also easily secured.

### <8. Modification Examples>

Next, several modification examples will be described. Note that a constitution other than that described below in each modification example is the same as the constitution of the above embodiment.

### First Modification Example

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 by using an adhesive or other fixing means. In these cases, potting may be performed to fill a gap between the bus bar 42 and the accommodation portion 55.

### Second Modification Example

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by part of the flat surface portion 51 following the outer shape of the bus bar 42. In the present disclosure, “sheet-shape” or “sheet” is not limited to a member having a thickness of 1 mm or more, and may be a member (so-called film) having a thickness of less than 1 mm.

### Third Modification Example

The base plate 41 of the routing board 40 may include a plurality of members (plate members or sheet members). The plurality of members are provided to sandwich the plurality of bus bars 42 arranged in the horizontal direction, for example, from both sides in the Z direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed. For example, in this case, the accommodation portion 55 formed between the plurality of members corresponds to an example of an “accommodation portion recessed in the first direction (Z direction)”.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

Several embodiments and modification examples have been described above. However, the embodiments and the modification examples are not limited to the examples described above. For example, a plurality of embodiments may be implemented in combination with each other. The present invention is not limited by the above description, but only by the appended claims.

In the above-described embodiment, the electrical connection unit 1 for a vehicle has been described, but the present invention is not limited to this constitution.

In the above-described embodiment, the case where the two subunits SUX and SUY are a first circuit constitution body and one subunit SUZ is a second circuit constitution body has been described, but the present invention is not limited to this constitution. The number of the second circuit constitution bodies may be plural, or the number of the first circuit constitution bodies and the number of the second circuit constitution bodies may be the same.

In the above-described embodiment, the constitution in which the subunits SUX, SUY, and SUZ are arranged in a line in the X direction has been described, but the present invention is not limited to this constitution. The subunits SUX, SUY, and SUZ may be arranged in the X direction and the Y direction, or may be arranged in the Z direction.

In the above-described embodiment, the constitution in which the metal plate 80 overlaps the entire subunit SU has been described, but the present invention is not limited to this constitution. The metal plate 80 may overlap each of the subunits SU at least partially.

In the above-described embodiment, the constitution in which the subunits SU are electrically connected to each other has been described, but the present invention is not limited to this constitution. The subunits SU may be thermally connected to each other via the metal plate 80, and the subunits SU need not be directly connected to each other.

In the above-described embodiment, the constitution in which the routing board 40 and the bus bar 42 are integrally formed has been described, but the present invention is not limited to this constitution. The bus bar 42 may be formed separately from the routing board 40.

In the above-described embodiment, the constitution in which the heat dissipation portion is connected to the subunit SU via the heat transfer member 92 or the insulating sheet 91 has been described, but the present invention is not limited to this constitution. The heat dissipation portion may be directly connected to the subunit SU.

In the above-described embodiment, the constitution in which the metal plate 80 serving as a heat dissipation portion is formed in a plate shape disposed on one side in the Z direction with respect to the subunit SU has been described, but the present invention is not limited to this constitution. The heat dissipation portion may be provided to surround the periphery of the subunit SU.

Although the embodiments of the present disclosure have been described and illustrated above, the embodiments are illustrated as examples and are not intended to limit the scope of the present disclosure. The above-described embodiments can be implemented in various other forms, and the constituents in the above-described embodiments can be replaced with well-known constituents, and various additions, omissions, substitutions, and changes can be made without departing from the concept of the present disclosure.

### INDUSTRIAL APPLICABILITY

According to the present disclosure, it is possible to provide an electrical connection unit capable of improving a heat dissipation property.

### REFERENCE SIGNS LIST

1 Electrical connection unit
10, 10X Electronic component (first electronic component)
10, 10Y Electronic component (first electronic component)
10, 10Z Electronic component (second electronic component)
40, 40X First routing board (first board)
40, 40Y Second routing board (first board)
40, 40Z Third routing board (second board)
42 Bus bar (first bus bar, second bus bar)
55 Accommodation portion (first accommodation portion, second accommodation portion)
80 Metal plate (heat dissipation portion)
81 Flat surface portion
82 Fixing portion (first support portion, second support portion)
91 Insulating sheet (insulating member)
92 Heat transfer member
SU, SUX First subunit (first circuit constitution body)
SU, SUY Second subunit (first circuit constitution body)
SU, SUZ Third subunit (second circuit constitution body)

What is claimed is:

1. An electrical connection unit comprising:
a first circuit constitution body having a plurality of first electronic components and a first board on which the plurality of first electronic components are mounted;
a second circuit constitution body having a plurality of second electronic components and a second board on which the plurality of second electronic components are mounted; and
a heat dissipation portion provided to overlap at least part of each of the first board and the second board, and thermally connected to each of the first board and the second board, wherein
the electrical connection unit is switchable between a first state in which an amount of heat generation of the first circuit constitution body is greater than an amount of heat generation of the second circuit constitution body, and a second state, different from the first state, in which the amount of heat generation of the second circuit constitution body is greater than the amount of heat generation of the first circuit constitution body.

2. The electrical connection unit according to claim 1, wherein
in a case where a thickness direction of the first board is a first direction and a direction intersecting the first direction is a second direction, the first circuit constitution body and the second circuit constitution body are disposed to be arranged in the second direction.

3. The electrical connection unit according to claim 2, wherein
an area of the heat dissipation portion as viewed from the first direction is larger than a total area of the first circuit constitution body and the second circuit constitution body as viewed from the first direction, and
the heat dissipation portion overlaps an entire portion of the first circuit constitution body and the entire second circuit constitution body when viewed from the first direction.

4. The electrical connection unit according to claim 1, wherein
an insulating member is provided between the heat dissipation portion and the first circuit constitution body and between the heat dissipation portion and the second circuit constitution body, and
the heat dissipation portion includes a metal plate provided to overlap at least part of each of the first board and the second board and thermally connected to each of the first board and the second board.

5. The electrical connection unit according to claim 1, wherein
the first circuit constitution body includes a first bus bar that electrically connects the plurality of first electronic components to each other,
the second circuit constitution body includes a second bus bar that electrically connects the plurality of second electronic components to each other,
a heat transfer member having elasticity is provided between the heat dissipation portion and the first circuit constitution body or between the heat dissipation portion and the second circuit constitution body, and
in a case where the thickness direction of the first board is the first direction, the heat transfer member is disposed at a position overlapping a connection portion between the first bus bar and the first electronic component or a connection portion between the second bus bar and the second electronic component when viewed from the first direction.

6. The electrical connection unit according to claim 5, wherein
a first accommodation portion that is recessed in the first direction or open in the first direction and accommodates the first bus bar is formed in the first board, and
a second accommodation portion that is recessed in the first direction or open in the first direction and accommodates the second bus bar is formed in the second board.

7. The electrical connection unit according to claim 2, wherein
the heat dissipation portion includes
a flat surface portion that overlaps the first board and the second board when viewed from the first direction,
a first support portion that protrudes from the flat surface portion in the first direction and supports the first board, and
a second support portion that protrudes from the flat surface portion in the first direction and supports the second board.

8. The electrical connection unit according to claim 1, wherein the first circuit constitution body and the second circuit constitution body are electrically connected to each other.
